(19) United States
(12) Patent Application Publication
(10) Pub. No.: US 2026/0128077 A1
(43) Pub. Date: May 7, 2026

(54) REFRESH RATE DETERMINATION USING BIT SHIFTING

(71) Applicant: Micron Technology, Inc., Boise, ID (US)

(72) Inventor: Geoffrey B. Luken, Boise, ID (US)

(21) Appl. No.: 19/373,812

(22) Filed: Oct. 30, 2025

Related U.S. Application Data
(60) Provisional application No. 63/716,582, filed on Nov. 5, 2024.

(51) Int. Cl. G11C 11/406

(52) U.S. Cl. CPC G11C 11/40626; G11C 11/40615

(57) ABSTRACT

Methods, systems, and devices for refresh rate determination using bit shifting are described. A memory system may obtain a first temperature range of a set of temperature ranges that includes an operating temperature measured at the memory system and receive a first set of bits that indicates a base refresh rate associated with a second temperature range of the set of temperature ranges. Further, the memory system may apply a quantity of bit shifts to the first set of bits to generate a second set of bits that indicates a second refresh rate based on a difference between the first temperature range and the second temperature range. The memory system may refresh during a first duration according to the second refresh rate indicated by the second set of bits.

### CROSS REFERENCE

The present Application for Patent claims priority to U.S. patent application Ser. No. 63/716,582 by Luken, entitled “REFRESH RATE DETERMINATION USING BIT SHIFTING,” filed Nov. 5, 2024, which is assigned to the assignee hereof, and which is expressly incorporated by reference in its entirety herein.

### TECHNICAL FIELD

The following relates to one or more systems for memory, including refresh rate determination using bit shifting.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports refresh rate determination using bit shifting in accordance with examples as disclosed herein.

FIG. 2A shows an example of a bit shifting scheme that supports refresh rate determination using bit shifting in accordance with examples as disclosed herein.

FIG. 2B shows an example of a graph that supports refresh rate determination using bit shifting in accordance with examples as disclosed herein.

FIG. 3 shows an example of a component diagram that supports refresh rate determination using bit shifting in accordance with examples as disclosed herein.

FIG. 4 shows a block diagram of a memory system that supports refresh rate determination using bit shifting in accordance with examples as disclosed herein.

FIG. 5 shows a flowchart illustrating a method or methods that support refresh rate determination using bit shifting in accordance with examples as disclosed herein.

### DETAILED DESCRIPTION

A memory system may perform a self-refresh operation. In some examples, the memory system may determine a frequency at which to perform the self-refresh operation based on an operating temperature of the memory system. Using other methods, the memory system may be configured with one or more refresh rate curves. Each refresh rate curve may indicate a relationship between a set of temperatures and a set of refresh rates. In some examples, the memory system may determine an operating temperature of the memory system and identify two temperatures of the set of temperatures that the operating temperature falls between (or temperature trip points). Further, the memory system may select a refresh rate curve from the one or more refresh rate curves and utilize the selected refresh rate curve to obtain a respective refresh rate for each of the identified temperatures.

The memory system may then estimate (or interpolate) a refresh rate corresponding to the operating temperature using refresh rates of the temperature trip points and refresh the memory system according to the estimated refresh rate. However, this method may not offer refresh rate flexibility. That is, the memory system may be unable to change the relationship between the set of refresh rates and the set of temperatures because the set of refresh rates are set with metal switches (e.g., hardcoded using read-only memory). Thus, as performance of the memory system changes, the relationship between the set of refresh rates and the set of temperatures may stay constant resulting in an inefficient system. Further, to implement this method, the memory system may include multiple pre-configured tables (e.g., the refresh rate curves) and multiple multiplexers which may consume valuable space in the memory system.

As described herein, the memory system may utilize bit shifting techniques to determine the frequency at which to perform the self-refresh operation. In some examples, the memory system may determine a refresh rate based on a base refresh rate and bit shifting scheme. A base refresh rate may be associated with a base temperature of a set of temperature ranges. If the operating temperature falls in a different temperature range than the base temperature range, then a bit shifting scheme may alter the base refresh rate indicator to determine the updated refresh rate. In this way, refresh rates may be determined algorithmically and the refresh rates may be adjusted by adjusting the base refresh rate. In some examples, the memory system may determine an operating temperature and obtain a first temperature range of a set of temperature ranges that includes the operating temperature. Further, the memory system may receive a first set of bits that indicates a base refresh rate associated with a second temperature range (e.g., the base temperature range) of the set of temperature ranges. Upon receiving the first set of bits, the memory system may apply a quantity of bit shifts to the first set of bits to generate a second set of bits that indicates a second refresh rate based on a difference between the first temperature range and the second temperature range. In some examples, if the first temperature range and the second temperature are adjacent to one another, the memory system may apply a single bit shift to the first set of bits. In such examples, the second refresh rate may be equal to the base refresh rate multiplied by two.

Further, the memory system may apply a second quantity of bit shifts to the second set of bits to generate a third set of bits that indicates a third refresh rate. In some examples, the memory system may apply a single bit shift to the second set of bits such that the third refresh rate is equal to the second refresh rate multiplied by two. Thus, the resulting second refresh rate and the resulting third refresh rate may correspond to the temperature trip points that surround the operating temperature. The memory system may then refresh the memory system. In some examples, the memory system may estimate (or interpolate) a refresh rate corresponding to the operating temperature using the second refresh rate and the third refresh rate and refresh the memory system according to the estimated refresh rate. Using the methods as described herein may allow for refresh rate flexibility. That is, the memory system may update the base refresh rate to track a performance of the memory system. Further, circuitry used to implement the methods as described herein may be less complex and consume less space when compared to other methods.

In addition to applicability in memory systems as described herein, techniques for refresh rate determination using bit shifting may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by applying a self-refresh rate that tracks with both a temperature and a performance of the memory system, which may extend the life of electronic devices and thereby reducing electronic waste, among other benefits.

Features of the disclosure are illustrated and described in the context of systems and architectures. Features of the disclosure are further illustrated and described in the context of a bit shifting scheme, a graph, a component diagram, and a flowchart.

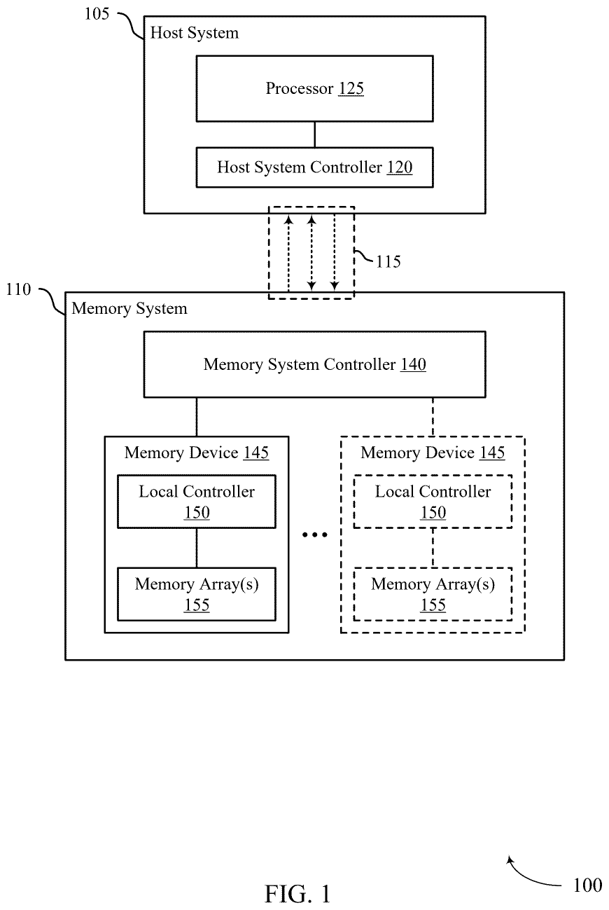

FIG. 1 shows an example of a system 100 that supports refresh rate determination using bit shifting in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

As described herein, the memory system 110 may utilize a bit-shifting scheme to determine a rate to perform a self-refresh operation. In some examples, the memory system 110 may obtain a first temperature range of a set of temperature ranges. The first temperature range may include an operating temperature measured at the memory system 110. Further, the memory system 110 may receive a first set of bits that indicates a base refresh rate associated with a second temperature range of the set of temperature ranges and apply a quantity of bit shifts to the first set of bits to generate a second set of bits based on a difference between the first temperature range and the second temperature range. In some examples, the second set of bits indicate a second refresh rate. The memory system 110 may then refresh, during a first duration, the memory system 110 according to the second refresh rate indicated by the second set of bits.

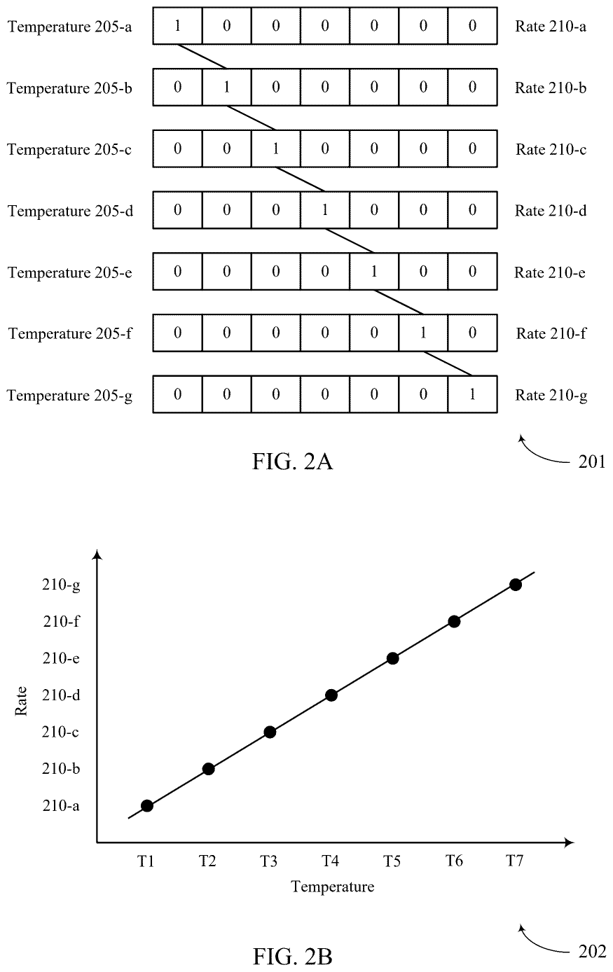

FIG. 2A shows an example of a bit shifting scheme 201 that supports refresh rate determination using bit shifting in accordance with examples as disclosed herein. In some examples, the bit shifting scheme 201 may implement or be implemented by aspects of the system 100. For example, the bit shifting scheme 201 may be implemented by the memory system 110 as described with respect to FIG. 1.

FIG. 2B shows an example of a graph 202 that supports refresh rate determination using bits shifting in accordance with examples as disclosed herein. In some examples, the graph 202 may implement or be implemented by aspects of the system 100. For example, the graph 202 may be implemented by the memory system 110 as described with respect to FIG. 1.

In some examples, a memory system may perform a self-refresh operation. During the self-refresh operation, the memory system may recharge memory cells to prevent data loss. In some examples, a rate at which the memory system performs the self-refresh operation (or refresh rate) may depend on a temperature of the memory system. For example, the memory system may be configured (or hard-coded) with one or more refresh rate curves. Each refresh rate curve may define a respective refresh rate for each temperature of a set of temperatures. As an example, the memory system may be configured with four refresh curves and each refresh curve may define a respective refresh rate for each temperature of a set of temperatures that includes 4 temperatures resulting in 16 possible refresh rate options.

In some examples, the set of temperatures may define one or more temperature ranges for the memory system. For example, if the set of temperatures includes 25 degrees Celsius, 41 degrees Celsius, and 57 degrees Celsius, the set of temperatures may define, at least, a first temperature range (e.g., 25 degrees Celsius to 40 degrees Celsius) and a second temperature range (e.g., 41 degrees Celsius to 56 degrees Celsius).

The memory system may determine the temperature of the memory system (e.g., using a temperature sensor included in the memory system) and identity a temperature range from the one or more temperature ranges that the temperature falls within. As an example, the memory system may determine that the temperature of the memory system is equal to 27 degrees Celsius and identify that the temperature falls within the first temperature range (e.g., 25 degrees Celsius to 40 degrees Celsius). Further, the memory system may identify a refresh curve from the one or more configured refresh curves and utilize the identified refresh curve along with the temperature to determine the frequency that the memory system may perform the self-refresh operation.

Because the temperature falls between two temperatures of the set of temperatures (e.g., is not equal to 25 degrees Celsius or 41 degrees Celsius), the memory system may determine two refresh rates. The two refresh rates may include the refresh rates that the identified refresh curve defines for each of the temperatures of the temperature range for which the temperature falls between. For example, the memory system may determine a first refresh rate defined for 25 degrees Celsius and a second refresh rate defined for 41 degrees Celsius. The memory system may then perform the self-refresh in accordance with the two refresh rates. In some examples, the memory system may switch between the two different refresh rates such that the resulting average refresh rate corresponds to the determined temperature.

In some examples, the memory system may generate the two refresh rates using tables of configured refresh rates in combination with multiplexers. However, including such circuitry in the memory system may take up valuable space. Further, such circuitry may not allow for flexibility. That is, the memory system may not be able to dynamically update the configured refresh rates because each refresh rate option is manually set with metal switches.

As described herein, the memory system may exploit bit-shifting to determine the frequency to perform the self-refresh operation. In some examples, the memory system may identify a set of temperatures ranges. For example, the memory system may identify a first temperature range between a temperature 205-a and a temperature 205-b, a second temperature range between the temperature 205-b and a temperature 205-c, a third temperature range between the temperature 205-c and a temperature 205-d, a fourth temperature range between the temperature 205-d and a temperature 205-e, a fifth temperature range between the temperature 205-e and a temperature 205-f, and a sixth temperature range between the temperature 205-f and a temperature 205-g. In some examples, the temperatures 205 of the set of temperatures 205 may increase in value starting from the temperature 205-a (or the lowest temperature) to the temperature 205-g (or the highest temperature).

Further, the memory system may identify a base rate option. The base rate option may indicate a relationship between a set of bits, a temperature range of the set of temperature ranges, and a refresh rate 210. In the example of FIG. 2A, the base rate option may indicate a relationship between the first temperature range (or the temperature range between the temperature 205-a and the temperature 205-b), the refresh rate 210-a, and a first set of bits. As shown in FIG. 2A, the first set of bits may include 100000 and may be associated with a base temperature range. However, other logic values for the first set of bits may be possible. In some examples, the base refresh rate may be associated with the base temperature range, and, by extension, the base refresh rate may be associated with first set of bits (e.g., 100000). Other refresh rates would be determined by bit shifting the bits and combining the new bit values with the base refresh rate.

Upon identifying the base rate option, the memory system may determine an operating temperature of the memory system (e.g., using the temperature sensor) and determine a temperature range of the set of temperature ranges that the operating temperature falls within. As an example, the memory system may determine that the operating temperature falls within the second temperature range (e.g., the temperature range between the temperature 205-b and the temperature 205-c).

In some examples, the memory system may compare the temperature range of the base rate option with the temperature range of the operating temperature and apply a quantity of bit shifts to the first set of bits based on the comparison. For example, the memory system may apply one bit shift to the first set of bits to generate a second set of bits that includes 0100000 based on a comparison of the first temperature range and the second temperature range. Applying one bit shift to the first set of bits may include dropping one or more bits of the first set of bits and shifting the remaining bits to a less significant bit position. Although FIG. 2A illustrates right bit shifting, other types of bit shifting (e.g., left bit shifting) may be applicable.

In some examples, the further away the temperature range corresponding to the operating temperature is from the temperature range corresponding to the base rate option, the more bit shifts that the memory system may apply to the first set of bits. For example, if the operating temperature falls within the third temperature range (e.g., the temperature range between the temperature 205-c and the temperature 205-d), the memory system may apply two bits shifts to the first set of bits to generate a second set of bits that includes 0010000 and so on.

In some examples, the second set of bits may indicate a first refresh rate 210. Each bit shift of a quantity of bit shifts applied to the first set of bits may indicate to multiply the refresh rate 210-a (or the base rate) by two or, in other words, divide a duration between self-refresh operations as indicated by the base rate by two. Thus, one bit shift applied to the first set of bits (or 0100000) may indicate a refresh rate 210-b that is equal to the refresh rate 210-a multiplied by two. Alternatively, two bit shifts applied to the first set of bits (or 0010000) may indicate a refresh rate 210-c that is equal to the refresh rate 210-a multiplied by four. As shown in FIG. 2A, other bit shifts are possible. For example, 3 bit shifts which results in a first set of bits that includes 0001000 and indicates a refresh rate 210- d, 4 bit shifts which results in a first set of bits that includes 0000100 and indicates a refresh rate 210-e, 5 bit shifts which results in a first set of bits that includes 0000010 and indicates a refresh rate 210-f, and 6 bit shifts which results in a first set of bits that includes 0000001 and indicates a refresh rate 210-g.

Upon determining the first refresh rate 210, the memory system may determine second refresh rate 210. To determine the second refresh rate 210, the memory system may apply a second quantity of bit shifts to the first set of bits or the second set of bits to generate a third set of bits. For example, the memory system may apply one bit shift to the second set of bits to generate the third set of bits. As an example, the memory system may apply one bit shift to the second set of bits that includes 0100000 to generate the third set of bits that includes 0010000. In such case, the third set of bits may indicate the refresh rate 210-c which may be equal to the refresh rate 210-b multiplied by 2 or the refresh rate 210-a (or the base rate) multiplied by four. Thus, the memory system may determine the first refresh rate as the refresh rate 210-b and the second refresh rate as the refresh rate 210-c.

Upon determining the first refresh rate 210 and the second refresh rate 210, the memory system may perform the self-refresh operation according to the first refresh rate and the second refresh rate. In some examples, the memory system may switch between the first refresh rate 210 and the second refresh rate 210 such that the resulting average refresh rate corresponds to the operating temperature. FIG. 2B illustrates the log-linear relationship between the operating temperature and the refresh rate created by the bit shifting scheme 201. In some examples, T1, T2, T3, T4, T5, T6, and T7 may correspond to the temperature 205-a, the temperature 205-b, the temperature 205-c, the temperature 205-d, the temperature 205-e, the temperature 205-f, and the temperature 205-g, respectively. As shown in FIG. 2B, the refresh rate 210 may increase as operating temperature of the memory system increases.

Using the methods as described herein may allow the memory system to use less complex circuitry as compared to other methods. Further, using the methods as described herein, the memory system may potentially update the refresh rates 210 simply by changing the base rate option allowing for more flexibility when compared to other methods.

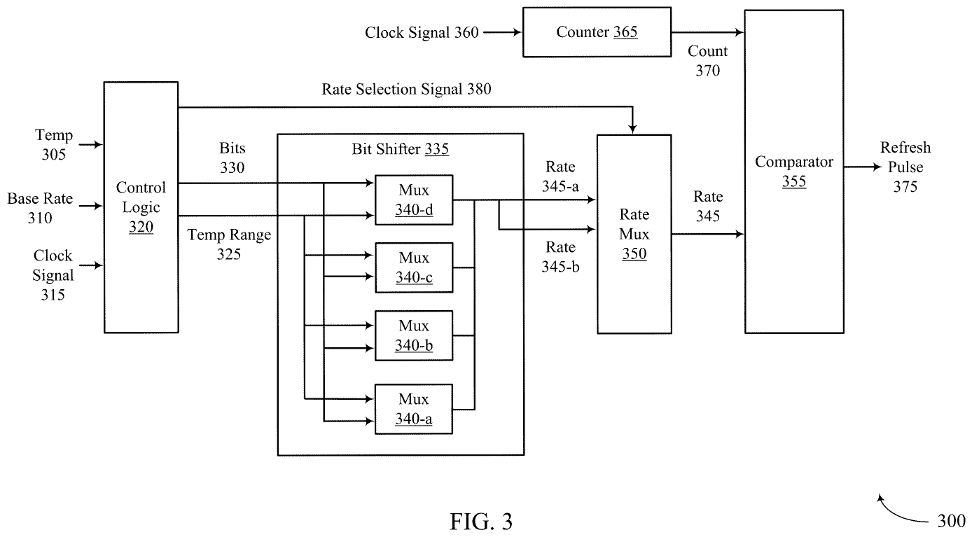

FIG. 3 shows an example of a component diagram 300 that supports refresh rate determination using bit shifting in accordance with examples as disclosed herein. In some examples, the component diagram 300 may be implemented by the system 100 as described with reference to FIG. 1. For example, the component diagram 300 may be included in a memory system 110 as described with reference to FIG. 1.

The component diagram 300 may include components collectively configured to determine a frequency for a memory system to perform a self-refresh operation. As shown in FIG. 3, the components of the component diagram 300 may include one or more of control logic 320, a bit shifter 335, a rate multiplexer 350, a comparator 355 and a counter 365. In some examples, the memory system may monitor a temperature 305 of the memory system and transmit a signal indicating the temperature 305 to the control logic 320. Additionally, the memory system may determine a base rate 310 (or base refresh rate) and transmit a signal indicating the base rate 310 to the control logic 320. Additionally, the memory system may transmit a clock signal 315 to the control logic 320. In some examples, the clock signal 315 may indicate each occurrence of a refresh event (e.g., or a refresh pulse).

Upon receiving the signal indicating the temperature 305 of the memory system, the control logic 320 may select a temperature range 325 from a set of temperature ranges 325 (e.g., a set of temperature ranges configured for the memory system). In some examples, the selected temperature range may include the temperature 205. In the example of FIG. 3, the set of temperature ranges may include a first temperature range, a second temperature range, a third temperature range, and a fourth temperature range. The first temperature range may include temperatures less than the second temperature range, the second temperature range may include temperatures less than the third temperature range, and the third temperature range may include temperature less than the fourth temperature range. The control logic 320 may then transmit bits 330 to the bit shifter 335. In some examples, the bits 330 may indicate the base rate 310. As an example, the bits 330 may include 1000 and may correspond to the first temperature range.

In some examples, upon receiving the bits 330, the bit shifter 335 may route one or more bits of the bits 330 to respective multiplexers 340. For example, the bit shifter 335 may route a first bit of the bits 330 (e.g., 1) to a multiplexer 340-a, the first bit and a second bit of the bits 330 (e.g., 10) to a multiplexer 340-b, the first bit, the second bit, and a third bit of the bits 330 (e.g., 100) to a multiplexer 340-c, and the first bit, the second bit, the third bit, and a fourth bit of the bits 330 (e.g., 1000) to a multiplexer 340-d. Additionally, the control logic 320 may transmit a signal indicating the temperature range 325 to the bit shifter 335 and the bit shifter 335 may route the signal indicating the temperature range 325 to each of the multiplexers 340.

In some examples, the multiplexers 340 may be configured to select an output based on the signal indicating the temperature range 325. For example, if the temperature range includes the first temperature range, the multiplexers 340 may not change a logic value of the bits 330. That is, the bit shifter 335 may not apply a bit shift to the bits 330 and may output second bits with the same logic value as the bits 330 (e.g., 1000). In another example, if the temperature range 325 includes the second temperature range, the multiplexer 340-a may select its output to be 0, the multiplexer 340-b may select its output to be the first bit of the bits 330 (e.g., 1), the multiplexer 340-c may select its output to be the second bit of the bits 330 (e.g., 0), and the multiplexer 340-d may select its output to be the third bit of the bits 330 (e.g., 0). That is, the bit shifter 335 may apply one bit shift to the bits 330 resulting in third bits (e.g., 0100).

In yet another example, if the temperature range 325 includes the third temperature range, the multiplexer 340-a may select its output to be 0, the multiplexer 340-b may select its output to be 0, the multiplexer 340-c may select its output to be the first bit of the bits 330 (e.g., 1), and the multiplexer 340-d may select its output to be the second bit of the bits 330 (0). That is, the bit shifter 335 may apply two bit shifts to the bits 330 resulting in fourth bits (e.g., 0010). In yet another example, if the temperature range 325 includes the fourth temperature range, the multiplexer 340-a may select its output to be 0, the multiplexer 340-b may select its output to be 0, the multiplexer 340-c may select its output to be 0, and the multiplexer 340-d may select its output to be the first bit of the bits 330 (e.g., 1). That is, the bit shifter 335 may apply three bit shifts to the bits 330 resulting in fifth bits (e.g., 0001). In some examples, the quantity of multiplexers 340 may be equal to the quantity of temperature ranges 325 configured for the memory system.

In some examples, a voltage (e.g., Vₛₛ) may be supplied to one or more multiplexers 340 if a bit shift occurs such that the one or more of the multiplexers 340 may set their output to 0. For example, if the temperature range 325 includes the third temperature range, the voltage may be supplied to the multiplexer 340-a and the multiplexer 340-b such that they may set their respective output to 0.

The bit shifter 335 may transmit the bits collectively output from the multiplexers 340 to the rate multiplexer 350. In some examples, the bits collectively output from the multiplexer 340 may indicate a rate 345-a. For example, the second bits (or 1000) may indicate the base rate, the third bits (or 0100) may indicate the base rate multiplied by two, the fourth bits (or 0010) may indicate the base rate multiplied by four, and the fifth bits (or 0001) may indicate the base rate multiple by eight.

In some examples, the bit shifter 335 may also output a rate 345-b to the rate multiplexer 350. To determine the rate 345-b, the bit shifter 335 may apply a single bit shift to the bits collectively output from the multiplexers 340. That is, the rate 345-b may be equal to the rate 345-a multiplied by two. Upon receiving the rate 345-a and the rate 345-b, the rate multiplexer 350 may select between the rate 345-a and the rate 345-b. In some examples, the rate multiplexer 350 may select between the rate 345-a and the rate 345-b based on a rate selection signal 380 output from the control logic 320.

As described, the control logic 320 may receive clock signal 315. From the clock signal 315, the control logic 320 may determine an average refresh rate of the memory system and select between the rate 345-a and the rate 345-b such that the average refresh rate is equal to a refresh rate associated with the temperature 305. The result of this selection is then signaled to the rate multiplexer 350 via the rate selection signal 380. As such, the rate multiplexer 350 may select the rate 345-a and the rate 345-b during different period of operation.

Upon selecting the rate 345 (e.g., the rate 345-a or the rate 345-b), the rate multiplexer 350 may transmit the selected rate 345 to the comparator 355. In some examples, the comparator 355 may be coupled with a counter 365 that receives a clock signal 360 from the memory system. The clock signal 360 may include an oscillating signal and may indicate a quantity of oscillation periods that occur after a self-refresh operation. A value of the counter 365 may increment each time an oscillation period elapses and may be output to the comparator 355. The comparator 355 may compare the value (e.g., count 370) of the counter 365 to the rate 345 and output refresh pulse 375 each time the value of the counter 365 matches the rate 345. In response to the refresh pulse 375, the memory system may perform a self-refresh operations. Using the method as described herein may allow the memory system to select a frequency at which to perform a refresh operation with less complex circuitry as compared to other methods.

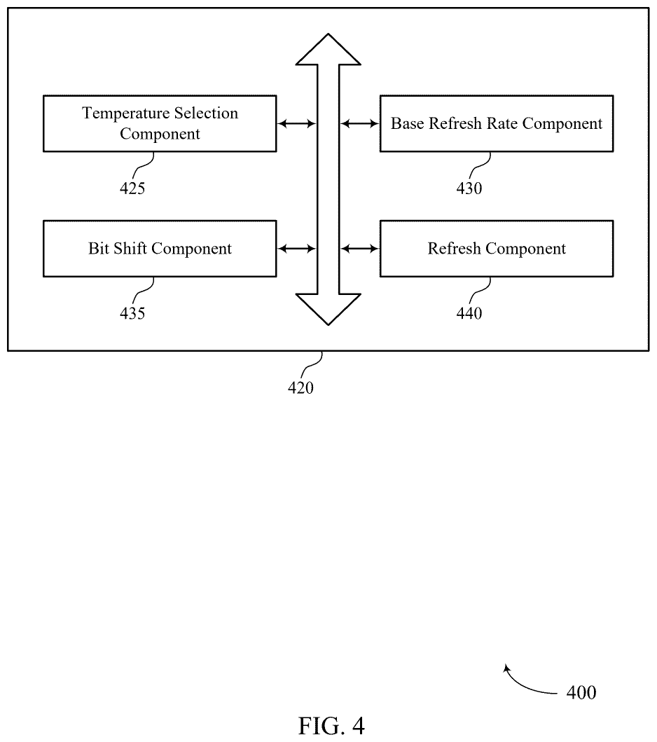

FIG. 4 shows a block diagram 400 of a memory system 420 that supports refresh rate determination using bit shifting in accordance with examples as disclosed herein. The memory system 420 may be an example of aspects of a memory system as described with reference to FIGS. 1 through 3. The memory system 420, or various components thereof, may be an example of means for performing various aspects of refresh rate determination using bit shifting as described herein. For example, the memory system 420 may include a temperature selection component 425, a base refresh rate component 430, a bit shift component 435, a refresh component 440, or any combination thereof. Each of these components, or components of subcomponents thereof (e.g., one or more processors, one or more memories), may communicate, directly or indirectly, with one another (e.g., via one or more buses).

The temperature selection component 425 may be configured as or otherwise support a means for obtaining a first temperature range of a plurality of temperature ranges, where the first temperature range includes an operating temperature measured at the memory system. The base refresh rate component 430 may be configured as or otherwise support a means for receiving a first set of bits that indicates a base refresh rate associated with a second temperature range of the plurality of temperature ranges. The bit shift component 435 may be configured as or otherwise support a means for applying a quantity of bit shifts to the first set of bits to generate a second set of bits based at least in part on a difference between the first temperature range and the second temperature range, the second set of bits indicating a second refresh rate. The refresh component 440 may be configured as or otherwise support a means for refreshing, during a first duration, the memory system according to the second refresh rate indicated by the second set of bits.

In some examples, the bit shift component 435 may be configured as or otherwise support a means for applying a second quantity of bit shifts to the second set of bits to generate a third set of bits that indicates a third refresh rate. In some examples, the refresh component 440 may be configured as or otherwise support a means for refreshing, during a second duration, the memory system according to the third refresh rate indicated by the third set of bits.

In some examples, to support applying the quantity of bit shifts to the first set of bits, the bit shift component 435 may be configured as or otherwise support a means for dropping one or more bits of the first set of bits. In some examples, to support applying the quantity of bit shifts to the first set of bits, the bit shift component 435 may be configured as or otherwise support a means for shifting the remaining bits of the first set of bits to a less significant bit position.

In some examples, the base refresh rate is less than the second refresh rate. In some examples, to support applying the one bit shift to the first set of bits, the bit shift component 435 may be configured as or otherwise support a means for dividing a duration between refreshes by two to generate the second refresh rate, the duration associated with the base refresh rate.

In some examples, to support applying the quantity of bit shifts to the first set of bits, the bit shift component 435 may be configured as or otherwise support a means for applying one bit shift to the first set of bits based at least in part on the first temperature range being adjacent to the second temperature range. In some examples, a quantity of temperature ranges including the plurality of temperature ranges is equal to a quantity of bits including the first set of bits.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

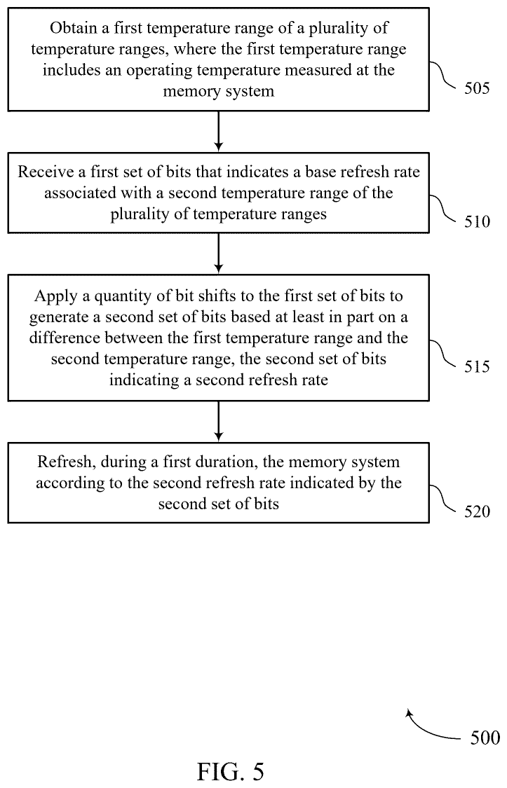

FIG. 5 shows a flowchart illustrating a method 500 that supports refresh rate determination using bit shifting in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include obtaining a first temperature range of a plurality of temperature ranges, where the first temperature range includes an operating temperature measured at the memory system. In some examples, aspects of the operations of 505 may be performed by a temperature selection component 425 as described with reference to FIG. 4.

At 510, the method may include receiving a first set of bits that indicates a base refresh rate associated with a second temperature range of the plurality of temperature ranges. In some examples, aspects of the operations of 510 may be performed by a base refresh rate component 430 as described with reference to FIG. 4.

At 515, the method may include applying a quantity of bit shifts to the first set of bits to generate a second set of bits based at least in part on a difference between the first temperature range and the second temperature range, the second set of bits indicating a second refresh rate. In some examples, aspects of the operations of 515 may be performed by a bit shift component 435 as described with reference to FIG. 4.

At 520, the method may include refreshing, during a first duration, the memory system according to the second refresh rate indicated by the second set of bits. In some examples, aspects of the operations of 520 may be performed by a refresh component 440 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for obtaining a first temperature range of a plurality of temperature ranges, where the first temperature range includes an operating temperature measured at the memory system; receiving a first set of bits that indicates a base refresh rate associated with a second temperature range of the plurality of temperature ranges; applying a quantity of bit shifts to the first set of bits to generate a second set of bits based at least in part on a difference between the first temperature range and the second temperature range, the second set of bits indicating a second refresh rate; and refreshing, during a first duration, the memory system according to the second refresh rate indicated by the second set of bits.
Aspect 2: The method, apparatus, or non-transitory computer-readable medium of aspect 1, further including operations, features, circuitry, logic, means, or instructions, or any combination thereof for applying a second quantity of bit shifts to the second set of bits to generate a third set of bits that indicates a third refresh rate.
Aspect 3: The method, apparatus, or non-transitory computer-readable medium of aspect 2, further including operations, features, circuitry, logic, means, or instructions, or any combination thereof for refreshing, during a second duration, the memory system according to the third refresh rate indicated by the third set of bits.
Aspect 4: The method, apparatus, or non-transitory computer-readable medium of any of aspects 1 through 3, where applying the quantity of bit shifts to the first set of bits includes operations, features, circuitry, logic, means, or instructions, or any combination thereof for dropping one or more bits of the first set of bits and shifting the remaining bits of the first set of bits to a less significant bit position.
Aspect 5: The method, apparatus, or non-transitory computer-readable medium of any of aspects 1 through 4, where the base refresh rate is less than the second refresh rate.
Aspect 6: The method, apparatus, or non-transitory computer-readable medium of any of aspects 1 through 5, where applying the quantity of bit shifts to the first set of bits includes operations, features, circuitry, logic, means, or instructions, or any combination thereof for applying one bit shift to the first set of bits based at least in part on the first temperature range being adjacent to the second temperature range.
Aspect 7: The method, apparatus, or non-transitory computer-readable medium of aspect 6, where applying the one bit shift to the first set of bits includes operations, features, circuitry, logic, means, or instructions, or any combination thereof for dividing a duration between refreshes by two to generate the second refresh rate, the duration associated with the base refresh rate.
Aspect 8: The method, apparatus, or non-transitory computer-readable medium of any of aspects 1 through 7, where a quantity of temperature ranges including the plurality of temperature ranges is equal to a quantity of bits including the first set of bits.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
obtain a first temperature range of a plurality of temperature ranges, wherein the first temperature range includes an operating temperature measured at the memory system;
receive a first set of bits that indicates a base refresh rate associated with a second temperature range of the plurality of temperature ranges;
apply a quantity of bit shifts to the first set of bits to generate a second set of bits based at least in part on a difference between the first temperature range and the second temperature range, the second set of bits indicating a second refresh rate; and
refresh, during a first duration, the memory system according to the second refresh rate indicated by the second set of bits.

2. The memory system of claim 1, wherein the processing circuitry is further configured to cause the memory system to:
apply a second quantity of bit shifts to the second set of bits to generate a third set of bits that indicates a third refresh rate.

3. The memory system of claim 2, wherein the processing circuitry is further configured to cause the memory system to:
refresh, during a second duration, the memory system according to the third refresh rate indicated by the third set of bits.

4. The memory system of claim 1, wherein, to apply the quantity of bit shifts to the first set of bits, the processing circuitry is configured to cause the memory system to:
drop one or more bits of the first set of bits; and
shift the remaining bits of the first set of bits to a less significant bit position.

5. The memory system of claim 1, wherein the base refresh rate is less than the second refresh rate.

6. The memory system of claim 1, wherein, to apply the quantity of bit shifts to the first set of bits, the processing circuitry is configured to cause the memory system to:
apply one bit shift to the first set of bits based at least in part on the first temperature range being adjacent to the second temperature range.

7. The memory system of claim 6, wherein, to apply the one bit shift to the first set of bits, the processing circuitry is configured to cause the memory system to:
divide a duration between refreshes by two to generate the second refresh rate, the duration associated with the base refresh rate.

8. The memory system of claim 1, wherein a quantity of temperature ranges comprising the plurality of temperature ranges is equal to a quantity of bits comprising the first set of bits.

9. A method by a memory system, comprising:
obtaining a first temperature range of a plurality of temperature ranges, wherein the first temperature range includes an operating temperature measured at the memory system;
receiving a first set of bits that indicates a base refresh rate associated with a second temperature range of the plurality of temperature ranges;
applying a quantity of bit shifts to the first set of bits to generate a second set of bits based at least in part on a difference between the first temperature range and the second temperature range, the second set of bits indicating a second refresh rate; and
refreshing, during a first duration, the memory system according to the second refresh rate indicated by the second set of bits.

10. The method of claim 9, further comprising:
applying a second quantity of bit shifts to the second set of bits to generate a third set of bits that indicates a third refresh rate.

11. The method of claim 10, further comprising:
refreshing, during a second duration, the memory system according to the third refresh rate indicated by the third set of bits.

12. The method of claim 9, wherein applying the quantity of bit shifts to the first set of bits comprises:
dropping one or more bits of the first set of bits; and
shifting the remaining bits of the first set of bits to a less significant bit position.

13. The method of claim 9, wherein the base refresh rate is less than the second refresh rate.

14. The method of claim 9, wherein applying the quantity of bit shifts to the first set of bits comprises:
applying one bit shift to the first set of bits based at least in part on the first temperature range being adjacent to the second temperature range.

15. The method of claim 14, wherein applying the one bit shift to the first set of bits comprises:
dividing a duration between refreshes by two to generate the second refresh rate, the duration associated with the base refresh rate.

16. The method of claim 9, wherein a quantity of temperature ranges comprising the plurality of temperature ranges is equal to a quantity of bits comprising the first set of bits.

17. A non-transitory computer-readable medium storing code, the code comprising instructions executable by one or more processors to:
obtain a first temperature range of a plurality of temperature ranges, wherein the first temperature range includes an operating temperature measured at a memory system;
receive a first set of bits that indicates a base refresh rate associated with a second temperature range of the plurality of temperature ranges;
apply a quantity of bit shifts to the first set of bits to generate a second set of bits based at least in part on a difference between the first temperature range and the second temperature range, the second set of bits indicating a second refresh rate; and
refresh, during a first duration, the memory system according to the second refresh rate indicated by the second set of bits.

18. The non-transitory computer-readable medium of claim 17, wherein the instructions are further executable by the one or more processors to:
apply a second quantity of bit shifts to the second set of bits to generate a third set of bits that indicates a third refresh rate.

19. The non-transitory computer-readable medium of claim 17, wherein the instructions to apply the quantity of bit shifts to the first set of bits are executable by the one or more processors to:
drop one or more bits of the first set of bits; and
shift the remaining bits of the first set of bits to a less significant bit position.

20. The non-transitory computer-readable medium of claim 17, wherein the instructions to apply the quantity of bit shifts to the first set of bits are executable by the one or more processors to:
apply one bit shift to the first set of bits based at least in part on the first temperature range being adjacent to the second temperature range.
